(19) United States
(12) Patent Application Publication
(10) Pub. No.: US 2026/0344215 A1
(43) Pub. Date: Oct. 29, 2026

(54) DISPLAY DEVICE AND DISPLAY PANEL

(71) Applicant: LG Display Co., Ltd., Seoul (KR)

(72) Inventors: YoungMin Jeong, Paju-si (KR); WonHo Lee, Paju-si (KR)

(73) Assignee: LG Display Co., Ltd., Seoul (KR)

(21) Appl. No.: 19/561,449

(22) Filed: Mar. 9, 2026

(30) Foreign Application Priority Data
Apr. 24, 2025 (KR) 10-2025-0053489

(51) Int. Cl. H10K 59/131; H10K 59/35

(52) U.S. Cl. CPC H10K 59/131; H10K 59/35

(57) ABSTRACT

A display device includes a structure where: a plurality of pixels each including a first subpixel, a second subpixel, and a third subpixel configured to emit light of different colors are disposed in a display panel; at least two adjacent pixels in a first direction among the plurality of pixels are connected to the same data line; and at least two subpixels in one pixel are connected to different gate lines. Accordingly, the display device is capable of effectively reducing the number of data channels.

### CROSS REFERENCE TO RELATED APPLICATION

This application claims priority from Korean Patent Application No. 10-2025-0053489, filed on Apr. 24, 2025, in the Korean Intellectual Property Office, which is hereby incorporated by reference for all purposes as if fully set forth herein.

### TECHNICAL FIELD

The present disclosure relates to electronic devices with displays, and more specifically, to display panels and display devices including the display panels.

### BACKGROUND

Among various types of display devices, organic light emitting display devices based on organic light emitting diodes (OLEDs) present advantages obtained by self-emissive properties, such as a short response time, a high contrast ratio, high luminous efficiency, luminance, a wide viewing angle, and the like, and such display devices have become increasingly attractive.

Demands for higher resolution and larger screen sizes of display devices are rapidly increasing, and to satisfy such demands, the number of data channels in a data driving circuit is also continuously increasing.

However, an increase in the number of data channels for supplying data voltages in a display device may cause the manufacturing cost of a data driving circuit to increase and the size of a bezel area connected to data channels to increase. Accordingly, there exists a need for reducing the number of data channels.

### SUMMARY

One or more aspects of the present disclosure may provide a display panel and a display device that include a structure where one pixel is configured with three subpixels, and the arrangements and interconnections of a plurality of pixels and a plurality of data lines are optimized or improved, and thereby, are capable of more effectively reducing the number of data channels.

One or more aspects of the present disclosure may provide a display panel and a display device that include a structure where a connection between a white subpixel and a white data line and a connection between a non-white subpixel and a non-white color data line are differently configured, and thereby, are capable of more effectively reducing the number of data channels.

One or more aspects of the present disclosure may provide a display panel and a display device that include a structure where white subpixels are disposed at equal intervals, and thereby, are capable of ensuring or improving luminance uniformity and being driven with low power.

One or more aspects of the present disclosure may provide a display panel and a display device that include a structure where the number of data channels is minimized or reduced, and thereby are capable of providing a light weight and low manufacturing costs, and ensuring a space margin.

One or more aspects of the present disclosure may provide a display panel and a display device that include a structure where a plurality of colors are sensed in a single scan operation, and thereby, are capable of reducing a time required to sense subpixels.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device may includes a display panel including a plurality of gate lines extending in a first direction, a plurality of data lines extending in a second direction intersecting the first direction, and a plurality of pixels each including a first subpixel, a second subpixel, and a third subpixel. In one or more aspects, one pixel among the plurality of pixels may be connected to a same data line as at least one other pixel adjacent to the one pixel in the first direction.

According to one or more example embodiments of the present disclosure, a display panel may includes a plurality of pixels that each include a first subpixel, a second subpixel, and a third subpixel configured emit light of different colors from each other, and that are connected to a first gate line and a second gate line, a first color data line running across first, second and third pixels among the plurality of pixels, a second color data line running across fourth, fifth and sixth pixels among the plurality of pixels, a first white data line running across the first and second pixels among the plurality of pixels, a second white data line running across the third and fourth pixels among the plurality of pixels, and a third white data line running across the fifth and sixth pixels among the plurality of pixels.

According to one or more example embodiments of the present disclosure, a display panel may include a plurality of gate lines extending in a first direction, a plurality of data lines extending in a second direction intersecting the first direction, and a plurality of pixels each comprising a plurality of subpixels, wherein a first pixel of the plurality of pixels is connected to the same data line with at least one adjacent other pixel in the first direction.

According to one or more aspects of the present disclosure, a display panel and a display device may be provided that are capable of more effectively reducing the number of data channels base on a structure where one pixel is configured with three subpixels, and the arrangements and interconnections of a plurality of pixels and a plurality of data lines are optimized or improved.

According to one or more aspects of the present disclosure, a display panel and a display device may be provided that are capable of more effectively reducing the number of data channels based on a structure where a connection between a white subpixel and a white data line and a connection between a non-white subpixel and a non-white color data line are differently configured.

According to one or more aspects of the present disclosure, a display panel and a display device may be provided that are capable of ensuring or improving luminance uniformity and being driven with low power based on a structure where white subpixels are disposed at equal intervals.

According to one or more aspects of the present disclosure, a display panel and a display device may be provided that are capable of providing a light weight and low manufacturing costs, and ensuring a space margin based on a structure where the number of data channels is minimized or reduced.

According to one or more aspects of the present disclosure, a display panel and a display device may be provided that are capable of reducing a time required to sense subpixels based on a structure where a plurality of colors are sensed in a single scan operation.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the present disclosure and are incorporated in and constitute a part of the disclosure, illustrate aspects of the disclosure and together with the description serve to explain principles of the disclosure. In the drawings:

FIG. 1 is a system configuration of an example display device according to aspects of the present disclosure;

FIG. 2 illustrates the configuration of an example subpixel included in the display device according to aspects of the present disclosure;

FIG. 3 illustrates the configuration of an example pixel included in the display device according to aspects of the present disclosure;

FIGS. 4 and 5 illustrate example arrangements of high voltage lines included in the display device according to aspects of the present disclosure;

FIG. 6 illustrates example arrangements of pixels included in the display device according to aspects of the present disclosure; and

FIGS. 7 to 10 illustrate example driving sequences for subpixels in pixels included in the display device according to aspects of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to more fully understand the scope of the present disclosure. Further, the protected scope of the present disclosure may be defined by claims and their equivalents. In the following description, where the detailed description of the relevant known function or configuration may unnecessarily obscure aspects of the present disclosure, a detailed description of such known function or configuration may be omitted.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including,” “having,” “containing,” “constituting,” “make up of,” and “formed of” used herein are generally intended to allow other components to be added unless the terms are used with a more specific term like “only.” As used herein, singular forms are intended to include plural forms, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to refer to one element separately from another. For example, a first element could be termed a second element, and, similarly, a second element could be termed a first element, without departing from the scope of the present disclosure.

Where the specification describes that a first element “is connected or coupled to,” “contacts,” or “overlaps” a second element, or the like, it should be interpreted that, not only can the first element “be directly connected or coupled to,” “directly contact,” or “directly overlap” the second element, but a third element can also be “interposed” between the first and second elements, or the first and second elements can “be connected or coupled to,” “contact,” or “overlap” each other via a fourth element. Here, the second element may be included in at least one of two or more elements that “are connected or coupled to,” “contact,” or “overlap with,” each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly),” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

In addition, where any dimensions, relative sizes, etc., are mentioned, it should be considered that numerical values for an elements or features, or corresponding information (e.g., level, range, and the like) include a tolerance or error range that may be caused by various factors (e.g., process factors, internal or external impact, noise, and the like) even where a relevant description of such tolerance or error range is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

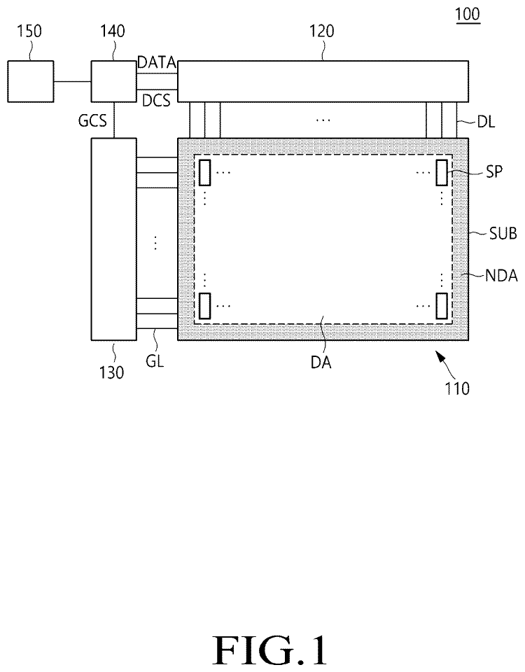

FIG. 1 is a system configuration of an example display device according to aspects of the present disclosure.

As shown in FIG. 1, in one or more example embodiments, a display device 100 may include a display panel 110 and at least one driving circuit for driving the display panel 110.

The at least one driving circuit may include a data driving circuit 120 and a gate driving circuit 130, and further include a controller 140 configured to control the data driving circuit 120 and the gate driving circuit 130. In one or more aspects, the at least one driving circuit may further include a power management circuit configured to supply driving voltages.

The display panel 110 may include a plurality of subpixels SP connected to a plurality of data lines DL and a plurality of gate lines GL.

In one or more aspects, the plurality of gate lines GL may extend in a first direction (e.g., the row direction), and the plurality of data lines DL may extend in a second direction (e.g., the column direction) intersecting the first direction.

For example, the plurality of subpixels SP may include a plurality of white subpixels configured to emit light of a white color, and a plurality of non-white subpixels configured to emit light of colors different from the white color.

For example, the plurality of non-white subpixels may include one or more red subpixels configured to emit light of a red color, one or more green subpixels configured to emit light of a green color, and one or more blue subpixels configured to emit light of a blue color.

However, aspects of the present disclosure are not limited thereto. For example, the plurality of subpixels may include one or more subpixels configured to emit light of magenta, yellow, cyan, and/or the like, which are different from the white color, red color, green color, and blue color.

In one or more aspects, a plurality of pixels may be disposed in the display panel 110, and each of the plurality of pixels may include a plurality of subpixels SP configured to emit respective colors. For example, the plurality of subpixels SP configured to emit different colors may be, for example, three subpixels adjacent to each other in a first direction.

Hereinafter, for convenience of description, the three subpixels included in one pixel may be referred to as a first subpixel, a second subpixel, and a third subpixel.

In one or more aspects, any one of a plurality of pixels may be connected to the same data line DL as one or more other pixels disposed in the first direction with respect to the one pixel.

Further, at least two of first, second, and third subpixels included in any one of the plurality of pixels may be connected to respective gate lines GL. For example, two gate lines GL may be disposed in each of the plurality of pixels.

The data driving circuit 120 may be a circuit for driving a plurality of data lines DL and can supply data signals to the plurality of data lines DL. The gate driving circuit 130 may be a circuit for driving a plurality of gate lines GL and can supply gate signals to the plurality of gate lines GL.

The controller 140 can supply a data control signal DCS to the data driving circuit 120 to control an operation time of the data driving circuit 120. The controller 140 can supply a gate control signal GCS to the gate driving circuit 130 to control an operation time of the gate driving circuit 130.

The controller 140 can control the initiation of scan operation for pixels according to respective times set in each frame. The controller 140 can convert image data received from an external device or system (e.g., a host system 150) to a data signal form readable by the data driving circuit 120, and supply image data DATA resulting from the converting to the data driving circuit 120. The controller 140 can control data driving at times set for scanning corresponding one or more of the pixels.

The controller 140 can receive display driving control signals along with image data from the external device or system (e.g., the host system 150). For example, the display driving control signals may include a vertical sync signal (VSYNC), a horizontal sync signal (HSYNC), an input data enable signal (DE), a clock signal (CLK), and the like. The controller 140 can generate several types of control signals such as data driving control signals DCS, gate driving control signals GCS, and the like based on the display driving control signals, and output the generated control signals (DCS and GCS) to the data driving circuit 120 and the gate driving circuit 130.

To control the gate driving circuit 130, the controller 140 can output several types of gate control signals GCS such as a gate start pulse (GSP), a gate shift clock (GSC), a gate output enable signal (GOE), and the like.

To control the data driving circuit 120, the controller 140 can output several types of data control signals DCS such as a source start pulse (SSP), a source sampling clock (SSC), a source output enable (SOE) signal, and the like.

The controller 140 may be implemented in a separate component from the data driving circuit 120, or integrated with the data driving circuit 120, so that the controller 140 and the data driving circuit 120 can be implemented in a single integrated circuit.

The data driving circuit 120 can drive a plurality of data lines DL by receiving image data DATA from the controller 140 and supplying data voltages to the plurality of data lines DL. The data driving circuit 120 may also be referred to as a source driving circuit.

The data driving circuit 120 may include one or more source driver integrated circuits (SDIC).

In one or more aspects, each source driver integrated circuit SDIC may be connected to the display panel 110 in a tape-automated-bonding (TAB) structure, or connected to a conductive pad such as a bonding pad of the display panel 110 in a chip-on-glass (COG) structure or a chip-on-panel (COP) structure, or connected to the display panel 110 in a chip-on-film (COF) structure.

The gate driving circuit 130 can output a gate signal having a turn-on voltage level or a gate signal having a turn-off voltage level by the control of the controller 140. The gate driving circuit 130 can sequentially drive a plurality of gate lines GL by sequentially supplying gate signals of the turn-on level voltage to the plurality of gate lines GL.

In one or more aspects, the gate driving circuit 130 may be connected to the display panel 110 in the tape-automated-bonding (TAB) structure, or connected to a conductive pad such as a bonding pad of the display panel 110 in the chip-on-glass (COG) structure or the chip-on-panel (COP) structure, or connected to the display panel 110 in the chip-on-film (COF) structure. In one or more aspects, the gate driving circuit 130 may be disposed in a non-display area NDA of the display panel 110 in a gate-in-panel (GIP) structure. The gate driving circuit 130 may be disposed on a substrate SUB, or connected to the substrate SUB. As such, in an example where the gate driving circuit 130 is implemented in the GIP structure, the gate driving circuit 130 may be disposed in the non-display area NDA of the substrate SUB. The gate driving circuit 130 may be connected to the substrate SUB in examples where the gate driving circuit 130 is implemented in the chip-on-glass (COG) structure, the chip-on-film (COF) structure, or the like.

In one or more aspects, at least one of the data driving circuit 120 and the gate driving circuit 130 may be disposed in a display area DA of the display panel 110. For example, at least one of the data driving circuit 120 and the gate driving circuit 130 may be disposed not to overlap with a plurality of subpixels SP, or disposed to overlap with one or more, or all, of the plurality of subpixels SP.

When one or more specific gate lines are driven by the gate driving circuit 130, the data driving circuit 120 can convert image data DATA received from the controller 140 into analog data voltages and supply the resulted data voltages to a plurality of data lines DL.

In one or more aspects, the data driving circuit 120 may be disposed in, and/or electrically connected to, but not limited to, only one side or edge (e.g., an upper portion or a lower portion) of the display panel 110. In one or more aspects, the data driving circuit 120 may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In one or more aspects, the gate driving circuit 130 may be located in, and/or electrically connected to, but not limited to, one side or edge (e.g., a left portion or a right portion) of the display panel 110. In one or more aspects, the gate driving circuit 130 may be located in, and/or electrically connected to, but not limited to, two sides or edges (e.g., a left portion and a right portion) of the display panel 110 or at least two of four sides or edges (e.g., an upper portion, a lower portion, the left portion, and the right portion) of the display panel 110 according to driving schemes, panel design schemes, or the like.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 120 and the gate driving circuit 130 through the printed circuit board, the flexible printed circuit, or the like.

In one or more aspects, the display device 100 may be a display including a backlight unit such as a liquid crystal display or the like, or be a self-emissive display such as an organic light emitting diode (OLED) display, a quantum dot (QD) display, a micro light emitting diode (micro LED) display, or the like.

In an example where the display device 100 according to aspects of the present disclosure is an OLED display or is implemented using an OLED display, each subpixel SP may include, as a light emitting element, an OLED, which is a self-emissive element. In an example where the display device 100 according to aspects of the present disclosure is a QD display or is implemented using a QD display, each subpixel SP may include a light emitting element configured with QDs, which are self-emissive semiconductor crystals. In an example where the display device 100 according to aspects of the present disclosure is a micro LED display or implemented using a micro LED display, each subpixel SP may include, as a light emitting element, a micro LED, which is a self-emissive element and includes an inorganic material.

In one or more aspects, the display panel 110 may have a top emission structure, a bottom emission structure, or a dual direction emission structure.

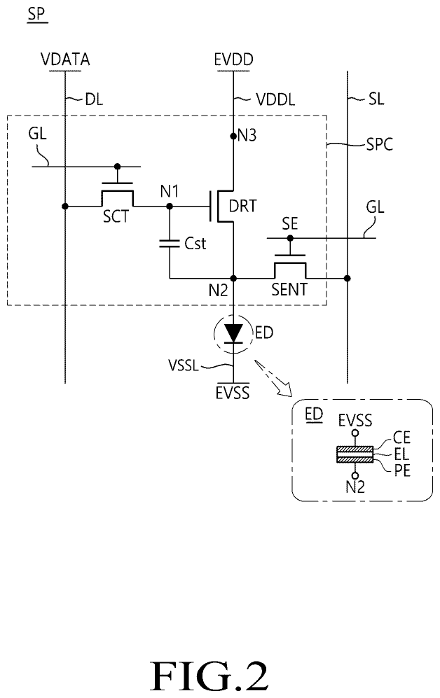

FIG. 2 illustrates the configuration of an example subpixel included in the display device 100 according to aspects of the present disclosure.

As shown in FIG. 2, in one or more example embodiments, each of subpixels SP included in the display device 100 may include a light emitting element ED and a subpixel circuit SPC for driving the light emitting element ED.

The subpixel circuit SPC may include a driving transistor DRT for driving the light emitting element ED, a scan transistor SCT connected to a first node N1 of the driving transistor DRT, a sensing transistor SENT connected to a second node N2 of the driving transistor DRT, and a storage capacitor Cst for maintaining a voltage for one frame at a constant level.

The light emitting element ED may include a pixel electrode PE and a common electrode CE, and may further include an emission layer EL located between the pixel electrode PE and the common electrode CE.

The pixel electrode PE of the light emitting element ED may be an electrode disposed for each subpixel SP, and the common electrode CE may be an electrode commonly disposed for all, or one or more, of subpixels SP.

For example, the pixel electrode PE may be an anode electrode and the common electrode CE may be a cathode electrode. In another example, the pixel electrode PE may be a cathode electrode and the common electrode CE may be an anode electrode.

The common electrode CE of the light emitting element ED may be connected to a low voltage line VSSL for delivering a low voltage EVSS such as a low power supply voltage and the like.

For example, the light emitting element ED may be at least one of an organic light emitting diode (OLED), a light emitting diode (LED), or a quantum dot (QD) light emitting element.

The driving transistor DRT may be a transistor for driving the light emitting element ED, and include the first node N1, the second node N2, and a third node N3.

The first node N1 of the driving transistor DRT may be the gate node of the driving transistor DRT, and may be electrically connected to the source or drain node of the scan transistor SCT.

The second node N2 of the driving transistor DRT may be the source or drain node of the driving transistor DRT, and may be electrically connected to the pixel electrode PE of the light emitting element ED.

The third node N3 of the driving transistor DRT may be the drain or source node of the driving transistor DRT, and may be electrically connected to a high voltage line VDDL for delivering a high voltage EVDD such as a high power supply voltage and the like.

The storage capacitor Cst may be connected between the first node N1 and the second node N2 of the driving transistor DRT.

The scan transistor SCT may be controlled by a gate signal and be connected between the first node N1 of the driving transistor DRT and a data line DL.

The scan transistor SCT may be turned on by a gate signal having a turn-on voltage level delivered through a gate line GL, and transfer a data voltage VDATA delivered through the data line DL to the first node N1 of the driving transistor DRT.

The sensing transistor SENT may be controlled by a gate signal and be connected between the second node N2 of the driving transistor DRT and a sensing line SL.

For example, the sensing transistor SENT may be turned on by a gate signal having a turn-on voltage level delivered through a gate line GL, and control a connection between the sensing line SL and the second node N2 of the driving transistor DRT.

The sensing transistor SENT may be turned on by the gate signal of the turn-on voltage level and transfer a reference voltage Vref delivered through the sensing line SL to the second node N2 of the driving transistor DRT.

Further, the sensing transistor SENT may be turned on by the gate signal of the turn-on voltage level and transfer a voltage of the second node N2 of the driving transistor DRT to the sensing line SL.

The function of the sensing transistor SENT to transfer the voltage of the second node N2 to the sensing line SL may be used in an operation where the subpixel SP is driven to sense unique characteristics of the driving transistor DRT and/or the light emitting element ED (e.g., the threshold voltage or mobility of the driving transistor DRT, and the like). In this example, the voltage transferred to the sensing line SL may be a voltage for calculating the unique characteristics of the subpixel SP or a voltage reflecting the unique characteristics of the subpixel SP.

As shown in FIG. 2, for example, the scan transistor SCT and the sensing transistor SENT may be connected to the same gate line GL.

In another example, the scan transistor SCT and the sensing transistor SENT may be connected to different gate lines GL. In this example, the scan transistor SCT may receive a scan gate signal having a turn-on voltage level from a scan gate line, which is a type of gate line GL, and control a connection between the data line DL and the first node N1 of the driving transistor DRT. Further, the sensing transistor SENT may receive a sensing gate signal having a turn-on voltage level from a sensing gate line, which is a type of gate line GL, and control a connection between the sensing line SL and the second node N2 of the driving transistor DRT.

Each of the driving transistor DRT, the scan transistor SCT, and the sensing transistor SENT may be an n-type transistor or a p-type transistor. Herein, for convenience of description, discussions are provided based on an example where each of the driving transistor DRT, the scan transistor SCT, and the sensing transistor SENT is an n-type transistor.

The structure of the subpixel SP illustrated in FIG. 2 is merely an example, and may be modified in various ways, such as by including one or more additional transistors or one or more additional capacitors.

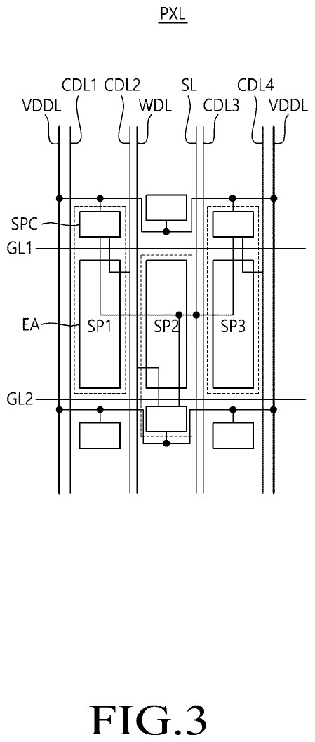

FIG. 3 illustrates the configuration of an example pixel included in the display device 100 according to aspects of the present disclosure.

As shown in FIG. 3, in some example embodiments, a plurality of subpixels SP disposed in the display device 100 may include a plurality of first subpixels SP1, a plurality of second subpixels SP2, and a plurality of third subpixels SP3. In one or more aspects, one pixel PXL may be configured with one first subpixel SP1, one second subpixel SP2, and one third subpixel SP3 located adjacent to each other in a first direction (e.g., the row direction).

The second subpixel SP2 in the one pixel PXL may be located between the first subpixel SP1 and the third subpixel SP3.

The second subpixel SP2 may be a white subpixel configured to emit white color light.

For example, the first subpixel SP1 may be a subpixel configured to emit light of one color among a plurality of non-white colors different from the white color. The third subpixel SP3 may be a subpixel configured to emit light of another color among the plurality of non-white colors.

For example, when the first subpixel SP1 is a red subpixel configured to emit red color light, the third subpixel SP3 may be a green subpixel configured to emit green color light or a blue subpixel configured to emit blue color light.

In another example, when the first subpixel SP1 is a green subpixel, the third subpixel SP3 may be a red subpixel or a blue subpixel.

In another example, when the first subpixel SP1 is a blue subpixel, the third subpixel SP3 may be a red subpixel or a green subpixel.

At least one of the first subpixel SP1, the second subpixel SP2, or the third subpixel SP3 in one pixel PXL may be designed with a flip structure in which respective positions of a corresponding light emitting area EA and a corresponding subpixel circuit SPC are reversed.

As shown in FIG. 3, the second subpixel SP2 may be designed with a regular arrangement structure in which the corresponding subpixel circuit SPC is located under the corresponding light emitting area EA, and the first subpixel SP1 and the third subpixel SP3 may be designed with a flip structure in which the corresponding subpixel circuits SPC are located over the corresponding light emitting areas EA.

However, aspects of the present disclosure are not limited thereto. For example, the second subpixel SP2 may be designed with the flip structure, or at least one of the first subpixel SP1 or the third subpixel SP3 may be designed with the regular arrangement structure.

The display device 100 according to one or more aspects of the present disclosure can provide advantages of preventing or suppressing the occurrence of short circuits between lines based on the arrangement optimization or improvement of data lines DL, high voltage lines VDDL, and sensing lines SL.

A plurality of data lines (CDL1 to CDL4) (hereinafter, which may be referred to as non-white color data lines (CDL1 to CDL4)) for delivering data voltages to non-white subpixels and one data line WDL (hereinafter, which may be referred to as a white data line WDL) for delivering a data voltage to a white subpixel may be disposed in one pixel PXL.

For example, the plurality of non-white color data lines (CDL1 to CDL4) may include at least one of a data line (hereinafter, which may be referred to as a red data line) for delivering a data voltage to a red subpixel, a data line (hereinafter, which may be referred to as a green data line) for delivering a data voltage to a green subpixel, or a data line (hereinafter, which may be referred to as a blue data line) for delivering a data voltage to a blue subpixel.

As shown in FIG. 3, the plurality of non-white color data lines (CDL1 to CDL4) may include a data line (hereinafter, which may be referred to as a first color data line CDL1) disposed in an area adjacent to one side of the first subpixel SP1, a data line (hereinafter, which may be referred to as a second color data line CDL2) disposed in an area adjacent to the other side of the first subpixel SP1 and one side of the second subpixel SP2.

Further, the plurality of non-white color data lines (CDL1 to CDL4) may include a data line (hereinafter, which may be referred to as a third color data line CDL3) disposed in an area adjacent to the other side of the second subpixel SP2 and one side of the third subpixel SP3, and a data line (hereinafter, which may be referred to as a fourth color data line CDL4) disposed in an area adjacent to the other side of the third subpixel SP3.

The white data line WDL may be a data line for delivering a data voltage to a white subpixel, and be located in an area adjacent to the other side of the first subpixel SP1 and one side of the second subpixel SP2. In other word, the white data line WDL may be located in the area between the first subpixel SP1 and the second subpixel SP2.

For example, in the area adjacent to the other side of the first subpixel SP1 and one side of the second subpixel SP2, the second color data line CDL2 may be disposed adjacent to the first subpixel SP1, and the white data line WDL may be disposed adjacent to the second subpixel SP2. In other word, the second color data line CDL2 may be disposed between the first subpixel SP1 and the white data line WDL, and the white data line WDL may be disposed between the second color data line CDL2 and the second subpixel SP2.

As shown in FIG. 3, for example, the first subpixel SP1 may be connected to the second color data line CDL2, the second subpixel SP2 may be connected to the white data line WDL, and the third subpixel SP3 may be connected to the fourth color data line CDL4.

However, aspects of the present disclosure are not limited thereto. For example, the first subpixel SP1 may be connected to the first color data line CDL1, or the third subpixel SP3 may be connected to the third color data line CDL3.

The first color data line CDL1 may be disposed between a high voltage line VDDL and the first subpixel SP1, and the fourth color data line CDL4 may be disposed between the third subpixel SP3 and another high voltage line VDDL.

The high voltage lines VDDL may be connected to each of the first to third subpixels (SP1 to SP3) through a first branch line having a zigzag shape. However, aspects of the present disclosure are not limited thereto. For example, the first branch line may be formed in a straight line shape.

As shown in FIG. 3, a sensing line SL may be disposed in an area adjacent to the other side of the second subpixel SP2 and one side of the third subpixel SP3. In other word, the sensing line SL may be located in the area between the second subpixel SP2 and the third subpixel SP3.

For example, in the area adjacent to the other side of the second subpixel SP2 and one side of the third subpixel SP3, the sensing line SL may be disposed adjacent to the second subpixel SP2, and the third color data line CDL3 may be disposed adjacent to the third subpixel SP3.

As shown in FIG. 3, the sensing line SL and each of the first to third subpixels (SP1 to SP3) may be connected to each other through a second branch line running across respective light emitting areas EA of the first to third subpixels (SP1 to SP3).

For example, the second branch line may be a transparent line and be disposed in a different layer from the plurality of data lines (CDL1 to CDL4, and WDL).

As shown in FIG. 3, two different gate lines (GL1 and GL2) may be disposed in one pixel PXL, and each of the first to third subpixels (SP1 to SP3) may be connected to any one of the two different gate lines (GL1 and GL2).

For example, the first subpixel SP1 and the third subpixel SP3 may be connected to the first gate line GL1, and the second subpixel SP2 may be connected to the second gate line GL2.

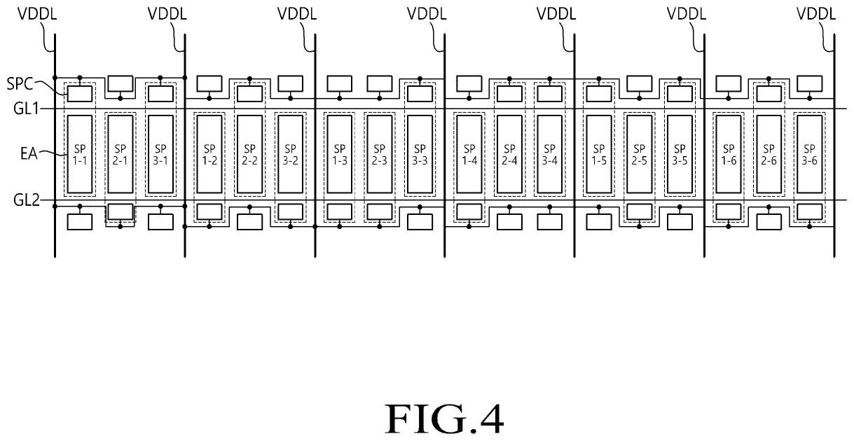

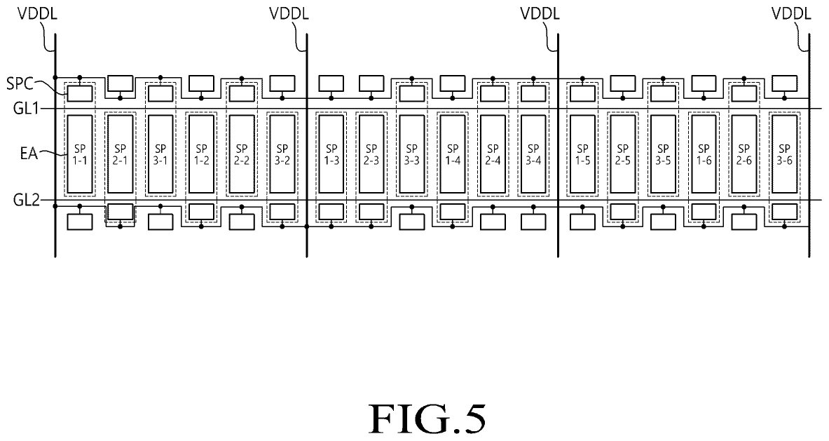

FIGS. 4 and 5 illustrate example arrangements of high voltage lines included in the display device 100 according to aspects of the present disclosure.

As shown in FIGS. 4 and 5, in some example embodiments, a plurality of pixels may include first to sixth pixels disposed in a first direction, and each of the first to sixth pixels may include a corresponding first subpixel among first subpixels (SP1-1 to SP1-6), a corresponding second subpixel among second subpixels (SP2-1 to SP2-6), and a corresponding third subpixel among third subpixels (SP3-1 to SP3-6).

As shown in FIG. 4, high voltage lines VDDL may be disposed in an area adjacent to one side of each of the first to sixth pixels and an area adjacent to the other side of each of the first to sixth pixels. In other word, each of the first to sixth pixels may be respectively disposed in an area between two adjacent high voltage lines among a plurality of high voltage lines VDDL.

For example, high voltage lines VDDL may be disposed in an area adjacent to one side of the first subpixel SP1-1 in the first pixel, an area adjacent to the other side of the third subpixel SP3-1 in the first pixel and one side of the first subpixel SP1-2 in the second pixel, an area adjacent to the other side of the third subpixel SP3-2 in the second pixel and one side of the first subpixel SP1-3 in the third pixel, and an area adjacent to the other side of the third subpixel SP3-3 in the third pixel and one side of the first subpixel SP1-4 in the fourth pixel, respectively.

Further, high voltage lines VDDL may be disposed in an area adjacent to the other side of the third subpixel SP3-4 in the fourth pixel and one side of the first subpixel SP1-5 in the fifth pixel, an area adjacent to the other side of the third subpixel SP3-5 in the fifth pixel and one side of the first subpixel SP1-6 in the sixth pixel, and an area adjacent to the other side of the third subpixel SP3-6 in the sixth pixel, respectively.

For example, in the display device 100 according to the example of FIG. 4, seven high voltage lines VDDL may be disposed for delivering a high voltage VDDL to the first to sixth pixels.

For example, in the display device 100 according to the example of FIG. 5, one adjacent pixel may be disposed in an area adjacent to the third subpixel of any one of the first to sixth pixels, and a high voltage line VDDL may not be disposed in an area between the third subpixel in the one pixel and the first subpixel in the one adjacent pixel. In other word, the high voltage line VDDL may not be disposed in an area between two adjacent pixels, either.

For example, a high voltage line VDDL may not be disposed in an area adjacent to the other side of the third subpixel SP3-1 in the first pixel and one side of the first subpixel SP1-2 in the second pixel, an area adjacent to the other side of the third subpixel SP3-3 in the third pixel and one side of the first subpixel SP1-4 in the fourth pixel, and an area adjacent to the other side of the third subpixel SP3-5 in the fifth pixel and one side of the first subpixel SP1-6 in the sixth pixel.

For example, high voltage lines VDDL may be disposed in an area adjacent to one side of the first subpixel SP1-1 in the first pixel, an area adjacent to the other side of the third subpixel SP3-2 in the second pixel and one side of the first subpixel SP1-3 in the third pixel, an area adjacent to the other side of the third subpixel SP3-4 in the fourth pixel and one side of the first subpixel SP1-5 in the fifth pixel, and an area adjacent to the other side of the third subpixel SP3-6 in the sixth pixel.

Accordingly, the display device 100 according to the example of FIG. 5 can reduce the number of high voltage lines VDDL for supplying the high voltage VDDL to the first to sixth pixels by allowing only four high voltage lines VDDL to be disposed. Thereby, the display device 100 can present an advantage of reducing the manufacturing cost.

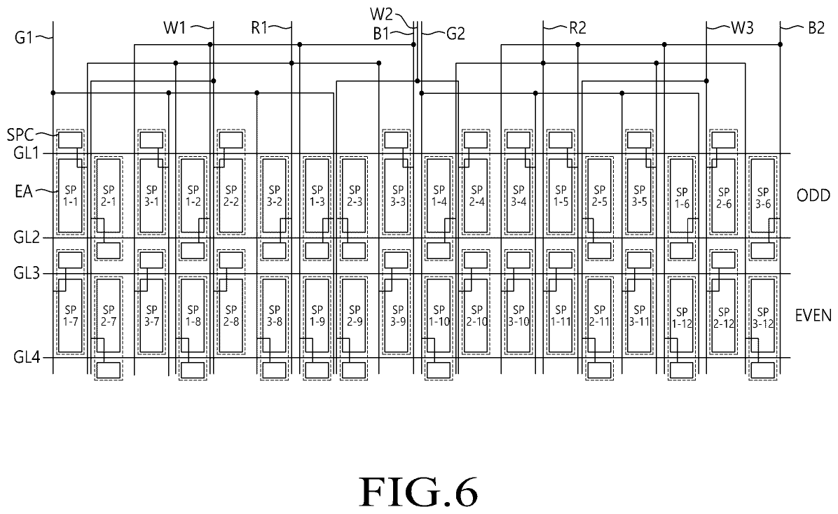

FIG. 6 illustrates example arrangements of pixels included in the display device 100 according to aspects of the present disclosure.

As shown in FIG. 6, in some example embodiments, a plurality of pixels included in the display device 100 may include first to sixth pixels disposed in one or more odd rows ODD, and seventh to twelfth pixels disposed in one or more even rows EVEN.

Although FIG. 6 illustrates, for convenience of explanation, only the first to twelfth pixels disposed in a 2×6 matrix form, however, the arrangement of the first to twelfth pixels disposed in the 2×6 matrix form may be repeated in the display panel 110 according to design requirements or specifications.

As shown in FIG. 6, each of the first to twelfth pixels may include a corresponding first subpixel among first subpixels (SP1-1 to SP1-12), a corresponding second subpixel among second subpixels (SP2-1 to SP2-12), and a corresponding third subpixel among third subpixels (SP3-1 to SP3-12).

The first to sixth pixels may be connected to a first gate line GL1 and a second gate line GL2, and the seventh to twelfth pixels may be connected to a third gate line GL3 and a fourth gate line GL4.

For example, among subpixels included in each of the first to sixth pixels, one or more subpixels having the flip structure may be connected to the first gate line GL1, and one or more subpixels having the regular arrangement structure may be connected to the second gate line GL2.

Further, among subpixels included in each of the 7th to 12th pixels, one or more subpixels having the flip structure may be connected to the third gate line GL3, and one or more subpixels having the regular arrangement structure may be connected to the fourth gate line GL4.

As shown in FIG. 6, for example, the first subpixel SP1-1 and the third subpixel SP3-1 in the first pixel, the second subpixel SP2-2 in the second pixel, the third subpixel SP3-3 in the third pixel, the second subpixel SP2-4 and the third subpixel SP3-4 in the fourth pixel, the first subpixel SP1-5 and the third subpixel SP3-5 in the fifth pixel, and the second subpixel SP2-6 in the pixel, which have the flip structure, may each be connected to the first gate line GL1.

For example, the second subpixel SP2-1 in the first pixel, the first subpixel SP1-2 and the third subpixel SP3-2 in the second pixel, the first subpixel SP1-3 and the second subpixel SP2-3 in the third pixel, the first subpixel SP1-4 in the fourth pixel, the second subpixel SP2-5 in the fifth pixel, and the first subpixel SP1-6 and the third subpixel SP3-6 in the sixth pixel, which have the regular arrangement structure, may each be connected to the second gate line GL2.

For example, the first subpixel SP1-7 and the third subpixel SP3-7 in the seventh pixel, the second subpixel SP2-8 in the eighth pixel, the third subpixel SP3-9 in the ninth pixel, the second subpixel SP2-10 and the third subpixel SP3-10 in the tenth pixel, the first subpixel SP1-11 and the third subpixel SP3-11 in the eleventh pixel, and the second subpixel SP2-12 in the twelfth pixel, which have the flip structure, may each be connected to the third gate line GL3.

For example, the second subpixel SP2-7 in the seventh pixel, the first subpixel SP1-8 and the third subpixel SP3-8 in the eighth pixel, the first subpixel SP1-9 and the second subpixel SP2-9 in the ninth pixel, the first subpixel SP1-10 in the tenth pixel, the second subpixel SP2-11 in the eleventh pixel, and the first subpixel SP1-12 and the third subpixel SP3-12 in the twelfth pixel, which have the regular arrangement structure, may each be connected to the fourth gate line GL4.

Each of the first to twelfth pixels may share the same data line DL with at least one adjacent other pixel in the first direction. Thereby, the display device 100 can present an advantage of effectively reducing the number of data channels in the data driving circuit 120.

In one or more aspects, a same white data line may be disposed in one pixel among the first to twelfth pixels and another pixel adjacent to the one pixel in the first direction.

For example, two adjacent white subpixels in the first direction may share the same white data line.

As shown in FIG. 6, a first white data line W1 may be disposed in the first pixel, the second pixel, the seventh pixel, and the eighth pixel, and the second subpixels (SP2-1, SP2-2, SP2-7, SP2-8) in the first pixel, the second pixel, the seventh pixel, and the eighth pixel may be connected to the first white data line W1.

For example, the first white data line W1 may be connected to a first white channel pad in the data driving circuit 120 and branched into two sub-lines, and the branched two sub-lines may be disposed in the first and seventh pixels, and the second and eighth pixels, respectively.

A second white data line W2 may be disposed in the third pixel, the fourth pixel, the ninth pixel, and the tenth pixel, and the second subpixels (SP2-3, SP2-4, SP2-9, SP2-10) in the third pixel, the fourth pixel, the ninth pixel, and the tenth pixel may be connected to the second white data line W2.

For example, the second white data line W2 may be connected to a second white channel pad in the data driving circuit 120 and branched into two sub-lines, and the branched two sub-lines may be disposed in the third and ninth pixels, and the fourth and tenth pixels, respectively.

A third white data line W3 may be disposed in the fifth pixel, the sixth pixel, the eleventh pixel, and the twelfth pixel, and the second subpixels (SP2-5, SP2-6, SP2-11, SP2-12) in the fifth pixel, the sixth pixel, the eleventh pixel, and the twelfth pixel may be connected to the third white data line W3.

For example, the third white data line W3 may be connected to a third white channel pad in the data driving circuit 120 and branched into two sub-lines, and the branched two sub-lines may be disposed in the fifth and eleventh pixels, and the sixth and twelfth pixels, respectively.

For example, the second subpixels (SP2-1 to SP2-12) in the first to twelfth pixels may be white subpixels.

As discussed above, the display device 100 may have the structure where white subpixels, which have the greatest influence on luminance of a displayed image, are disposed in second subpixels located at the center of each pixel so that the white subpixels are disposed at equal intervals in the display panel 110. Thereby, the display device 100 can provide advantages of ensuring or improving luminance uniformity of the display device 100 and improving image quality.

In one or more aspects, same color data lines may be disposed in one pixel among the first to twelfth pixels and two other pixels adjacent to the one pixel in the first direction. In other word, the same color data lines may be connected to the one pixel and two other pixels adjacent to the one pixel in the first direction.

For example, three subpixels having the same color and adjacent to each other in the first direction may share the same color data line.

As shown in FIG. 6, a first red data line R1, a first green data line G1, and a first blue data line B1 may be disposed in the first to third pixels and the seventh to ninth pixels, and a second red data line R2, a second green data line G2, and a second blue data line B2 may be disposed in the fourth to sixth pixels and the tenth to twelfth pixels.

For example, the first red data line R1, the first green data line G1, and the first blue data line B1 may be connected to a first red channel pad, a first green channel pad, and a first blue channel pad in the data driving circuit 120, respectively. Further, each of the first red data line R1, the first green data line G1, and the first blue data line B1 may be branched into three or four sub-lines, and the branched sub-lines may be disposed in the first and seventh pixels, the second and eighth pixels, and the third and ninth pixels, respectively.

Further, the second red data line R2, the second green data line G2, and the second blue data line B2 may be connected to a second red channel pad, a second green channel pad, and a second blue channel pad in the data driving circuit 120, respectively. Further, each of the second red data line R2, the second green data line G2, and the second blue data line B2 may be branched into three or four sub-lines, and the branched sub-lines may be disposed in the fourth and tenth pixels, the fifth and eleventh pixels, and the sixth and twelfth pixels, respectively.

For example, the first subpixel SP1-1 in the first pixel, the third subpixel SP3-2 in the second pixel, the first subpixel SP1-8 in the eighth pixel, and the third subpixel SP3-9 in the ninth pixel may be red subpixels and be connected to the first red data line R1.

The third subpixel SP3-1 in the first pixel, the first subpixel SP1-3 in the third pixel, the first subpixel SP1-7 in the seventh pixel, and the third subpixel SP3-8 in the eighth pixel may be green subpixels and be connected to the first green data line G1.

The first subpixel SP1-2 in the second pixel, the third subpixel SP3-3 in the third pixel, the third subpixel SP3-7 in the seventh pixel, and the first subpixel SP1-9 in the ninth pixel may be blue subpixels and be connected to the first blue data line B1.

The first subpixel SP1-4 in the fourth pixel, the third subpixel SP3-5 in the fifth pixel, the first subpixel SP1-11 in the eleventh pixel, and the third subpixel SP3-12 in the twelfth pixel may be red subpixels and be connected to the second red data line R2.

The third subpixel SP3-4 in the fourth pixel, the first subpixel SP1-6 in the sixth pixel, the first subpixel SP1-10 in the tenth pixel, and the third subpixel SP3-11 in the eleventh pixel may be green subpixels and be connected to the second green data line G2.

The first subpixel SP1-5 in the fifth pixel, the third subpixel SP3-6 in the sixth pixel, the third subpixel SP3-10 in the tenth pixel, and the first subpixel SP1-12 in the twelfth pixel may be blue subpixels and be connected to the second blue data line B2.

As discussed above, compared with an example structure where a total of 24 data channels (i.e., 6 white channels, 6 red channels, 6 green channels, and 6 blue channels) are needed to drive the first to twelfth pixels, the display device 100 according to aspects of the present disclosure can provide advantages of reducing the number of data channels for driving the first to twelfth pixels by using a total of 9 channels (i.e., 3 white channels, 2 red channels, 2 green channels, and 2 blue channels) based on the optimized or improved arrangement and connection structure of data lines.

In one or more aspects, at least one adjacent pixel among three or four pixels adjacent to one of the first to twelfth pixels in the first direction and a second direction different from the first direction may include a subpixel configured to emit light of a color not included in the one pixel.

For example, when the first subpixel SP1-2 in the second pixel is a blue subpixel, and the third subpixel SP3-2 in the second pixel is a red subpixel, at least one of the first pixel, the third pixel, or the eighth pixel adjacent to the second pixel may include a green subpixel.

Further, when the first subpixel SP1-10 in the tenth pixel is a green subpixel, and the third subpixel SP3-10 in the tenth pixel is a blue subpixel, at least one of the fourth pixel, the ninth pixel, or the eleventh pixel adjacent to the tenth pixel may include a red subpixel.

As shown in FIG. 6, the third subpixel SP3-1 in the first pixel, the first subpixel SP1-3 in the third pixel, and the third subpixel SP3-8 in the eighth pixel may be green subpixels.

Further, the first subpixel SP1-4 in the fourth pixel, the third subpixel SP3-9 in the ninth pixel, and the first subpixel SP1-11 in the eleventh pixel may be red subpixels.

As discussed above, as the display device 100 according to aspects of the present disclosure has the structure where white subpixels are disposed in respective pixels, and at least one red subpixel, at least one green subpixel, and at least one blue subpixel are disposed in at least two adjacent pixels without omission, the display device 100 can provide advantages of reducing the number of data pads based on the optimized or improved color arrangement of the subpixels without the degradation of display quality.

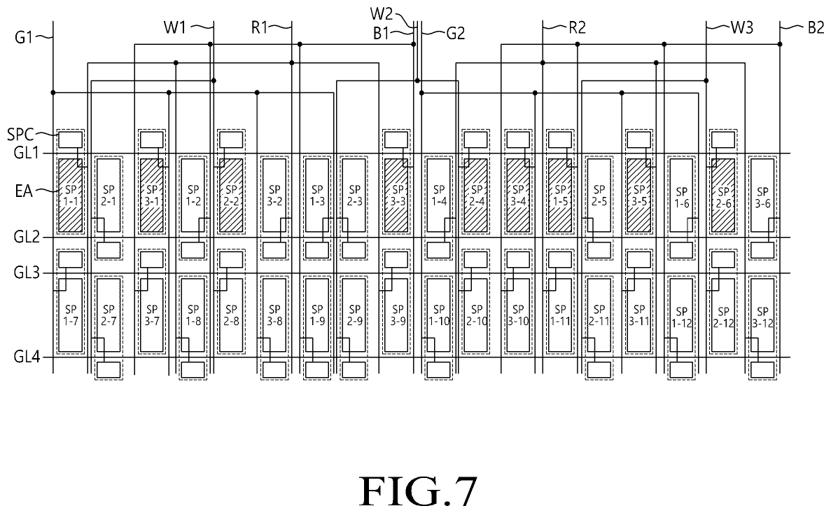

FIGS. 7 to 10 illustrate example driving sequences for subpixels in pixels included in the display device 100 according to aspects of the present disclosure.

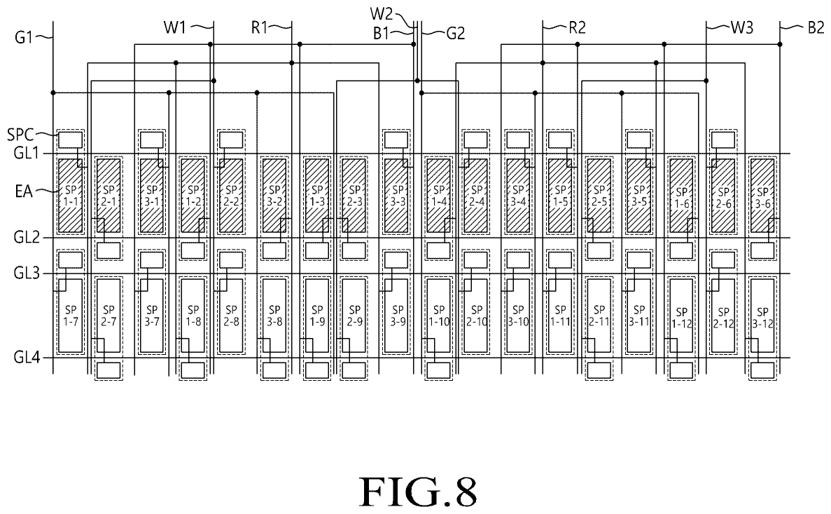

In some example embodiments, FIG. 7 illustrates a driving sequence of first to twelfth pixels by a scan operation in which a gate signal having a turn-on voltage level is applied to a first gate line GL1, and FIG. 8 illustrates a driving sequence of the first to twelfth pixels by a scan operation in which a gate signal having the turn-on voltage level is applied to a second gate line GL2.

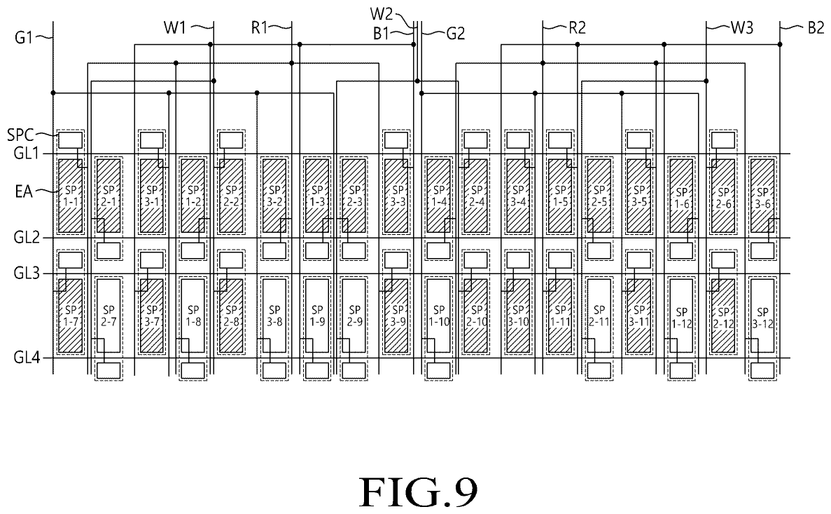

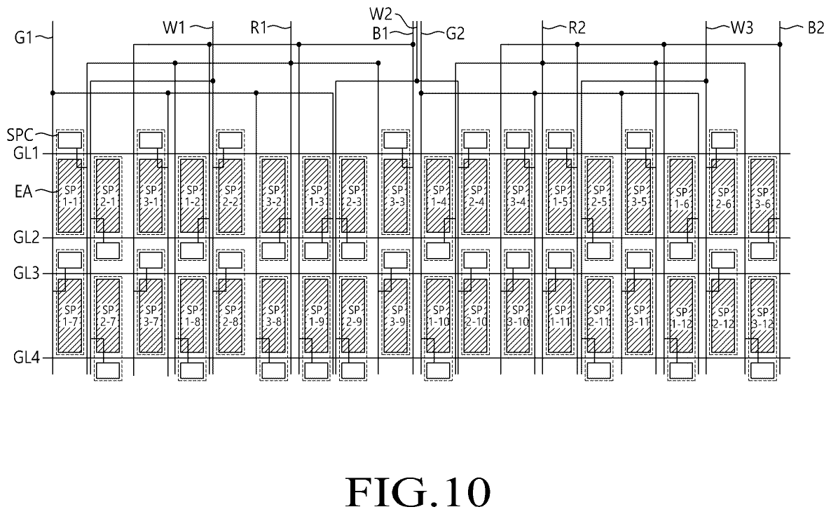

Further, FIG. 9 illustrates a driving sequence of the first to twelfth pixels by a scan operation in which a gate signal having the turn-on voltage level is applied to a third gate line GL3, and FIG. 10 illustrates a driving sequence of the first to twelfth pixels by a scan operation in which a gate signal having the turn-on voltage level is applied to a fourth gate line GL4.

As shown in FIGS. 7 to 10, while data voltage are delivered through a plurality of data lines (W1, W2, R1, R2, G1, G2, B1, and B2), when a gate signal having the turn-on voltage level is applied through the first gate line GL1, a sensing operation may be performed on subpixels connected to the first gate line GL1 in the first to sixth pixels.

As shown in FIG. 7, the subpixels connected to the first gate line GL1 may be a first subpixel SP1-1 and a third subpixel SP3-1 in the first pixel, a second subpixel SP2-2 in the second pixel, a third subpixel SP3-3 in the third pixel, a second subpixel SP2-4 and a third subpixel SP3-4 in the fourth pixel, a first subpixel SP1-5 and a third subpixel SP3-5 in the fifth pixel, and a second subpixel SP2-6 in the sixth pixel, which have the flip structure.

Thereafter, while data voltages are supplied through the plurality of data lines (W1, W2, R1, R2, G1, G2, B1, and B2), when a gate signal having the turn-on voltage level is applied through the second gate line GL2, a sensing operation may be performed on subpixels connected to the second gate line GL2 in the first to sixth pixels.

As shown in FIG. 8, the subpixels connected to the second gate line GL2 may be a second subpixel SP2-1 in the first pixel, a first subpixel SP1-2 and a third subpixel SP3-2 in the second pixel, a first subpixel SP1-3 and a second subpixel SP2-3 in the third pixel, a first subpixel SP1-4 in the fourth pixel, a second subpixel SP2-5 in the fifth pixel, and a first subpixel SP1-6 and a third subpixel SP3-6 in the sixth pixel, which have the regular arrangement structure.

Thereafter, while data voltages are supplied through the plurality of data lines (W1, W2, R1, R2, G1, G2, B1, and B2), when a gate signal having the turn-on voltage level is applied through the third gate line GL3, a sensing operation may be performed on subpixels connected to the third gate line GL3 in the seventh to twelfth pixels.

As shown in FIG. 8, the subpixels connected to the third gate line GL3 may be a first subpixel SP1-7 and a third subpixel SP3-7 in the seventh pixel, a second subpixel SP2-8 in the eighth pixel, a third subpixel SP3-9 in the ninth pixel, a second subpixel SP2-10 and a third subpixel SP3-10 in the tenth pixel, a first subpixel SP1-11 and a third subpixel SP3-11 in the eleventh pixel, and a second subpixel SP2-12 in the twelfth pixel, which have the flip structure.

Thereafter, while data voltages are supplied through the plurality of data lines (W1, W2, R1, R2, G1, G2, B1, and B2), when a gate signal having the turn-on voltage level is applied through the fourth gate line GL4, a sensing operation may be performed on subpixels connected to the fourth gate line GL4 in the seventh to twelfth pixels.

As shown in FIG. 10, the subpixels connected to the fourth gate line GL4 may be a second subpixel SP2-7 in the seventh pixel, a first subpixel SP1-8 and a third subpixel SP3-8 in the eighth pixel, a first subpixel SP1-9 and a second subpixel SP2-9 in the ninth pixel, a first subpixel SP1-10 in the tenth pixel, a second subpixel SP2-11 in the eleventh pixel, and a first subpixel SP1-12 and a third subpixel SP3-12 in the twelfth pixel, which have the regular arrangement structure.

The examples, aspects, and embodiments for the display device 100 and the display panel 110 described herein may be described as follows.

According to the one or more example embodiments described herein, a display device can be provided that includes a display panel including a plurality of gate lines extending in a first direction, a plurality of data lines extending in a second direction intersecting the first direction, a plurality of pixels each including a first subpixel, a second subpixel, and a third subpixel configured to emit light of different colors from each other, a gate driving circuit configured to drive the plurality of gate lines, and a data driving circuit configured to supply data voltages to the plurality of data lines. In one or more aspects, one pixel among the plurality of pixels may be connected to a same data line as at least one other pixel disposed in the first direction with respect to the one pixel, and at least two of the first subpixel, the second subpixel, or the third subpixel in the one pixel may be connected to different gate lines from each other.

In one or more aspects, the first subpixel included in the one pixel may be a subpixel configured to emit light of a first color among a plurality of colors different from a white color. In one or more aspects, the second subpixel included in the one pixel may be a subpixel configured to emit light of the white color. In one or more aspects, the third subpixel included in the one pixel may be a subpixel configured to emit light of a second color among the plurality of colors.

In one or more aspects, the plurality of colors may include at least one of red color, green color, or blue color.

In one or more aspects, the first subpixel or the third subpixel included in at least one adjacent pixel among three pixels adjacent to the one pixel in the first direction and the second direction may be a subpixel configured to emit light of a third color among the plurality of colors, wherein the third color is different from the first color and the second color.

In one or more aspects, a plurality of non-white color data lines and one white data line may be disposed in each of the plurality of pixels.

In one or more aspects, the same white data line may be disposed in the one pixel and another pixel adjacent to the one pixel in the first direction.

In one or more aspects, a same color data line may be disposed in the one pixel and two other pixels adjacent to the one pixel in the first direction.

In one or more aspects, at least one of the first subpixel, the second subpixel, or the third subpixel may have a flip structure in which the positions of a corresponding light emitting area and a corresponding subpixel circuit are reversed.

In one or more aspects, the second subpixel may be located between the first subpixel and the third subpixel.

In one or more aspects, the plurality of data lines are disposed respectively in an area adjacent to one side of the first subpixel, an area adjacent to the other side of the first subpixel and one side of the second subpixel, an area adjacent to the other side of the second subpixel and one side of the third subpixel, and an area adjacent to the other side of the third subpixel.

In one or more aspects, a sensing line is disposed in an area adjacent to the other side of the second subpixel and one side of the third subpixel.

In one or more aspects, the sensing line may be connected to each of the first subpixel, the second subpixel, and the third subpixel by a branch line running across respective light emitting areas of the first subpixel, the second subpixel, and the third subpixel.

In one or more aspects, the plurality of pixels may include an adjacent pixel adjacent to the third subpixel included in the one pixel.

In one or more aspects, the display device may have a structure where a high voltage line is disposed in an area adjacent to one side of the first subpixel in the one pixel and an area adjacent to the other side of the third subpixel in the adjacent pixel, but a high voltage line is not disposed in an area adjacent to the third subpixel in the one pixel and the first subpixel in the adjacent pixel.

In one or more aspects, the plurality of pixels may include a first pixel, a second pixel, a third pixel, a fourth pixel, a fifth pixel, and a sixth pixel sequentially disposed in at least one odd row among a plurality rows, and a seventh pixel, an eighth pixel, a ninth pixel, a tenth pixel, an eleventh pixel, and a twelfth pixel sequentially disposed to correspond to locations where the first to sixth pixels are disposed, respectively, in at least one even row among the plurality rows. In one or more aspects, the first to sixth pixels may be connected to a first gate line and a second gate line among the plurality of gate lines, and the seventh to twelfth pixels may be connected to a third gate line and a fourth gate line among the plurality of gate lines.

According to the one or more example embodiments described herein, a display panel can be provided that includes a plurality of pixels that each include a first subpixel, a second subpixel, and a third subpixel configured to emit light of different colors from each other, and that are connected to a first gate line and a second gate line, a first color data line running across first to third pixels among the plurality of pixels, a second color data line running across fourth to sixth pixels among the plurality of pixels, a first white data line running across the first and second pixels among the plurality of pixels, a second white data line running across the third and fourth pixels among the plurality of pixels, and a third white data line running across the fifth and sixth pixels among the plurality of pixels.

According to one or more example embodiments of the present disclosure, a display panel can be provided that includes a plurality of gate lines extending in a first direction, a plurality of data lines extending in a second direction intersecting the first direction, and a plurality of pixels each comprising a plurality of subpixels, wherein a first pixel of the plurality of pixels is connected to the same data line with at least one adjacent other pixel in the first direction.

In one or more aspects, the data line is a white data line, and the at least one adjacent other pixel includes a second pixel, and the white data line is disposed in the first pixel and second pixel of the plurality of pixels, and is connected to the first pixel and second pixel.

The above description has been presented to enable any person skilled in the art to make and use the technical idea of the present disclosure, and has been provided in the context of particular example applications. Various modifications, additions and substitutions to the described example embodiments will be readily apparent to those skilled in the art, and various principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device, comprising:
a display panel comprising a plurality of gate lines extending in a first direction, a plurality of data lines extending in a second direction intersecting the first direction, and a plurality of pixels each comprising a first subpixel, a second subpixel, and a third subpixel,
wherein one pixel among the plurality of pixels is connected to a same data line as at least one other pixel adjacent to the one pixel in the first direction.

2. The display device of claim 1, wherein the first subpixel, the second subpixel, and the third subpixel are configured to emit light of different colors from each other,
wherein the first subpixel included in the one pixel is a subpixel configured to emit light of one color among a plurality of colors different from a white color;
the second subpixel included in the one pixel is a subpixel configured to emit light of the white color; and
the third subpixel included in the one pixel is a subpixel configured to emit light of another color among the plurality of colors.

3. The display device of claim 2, wherein the plurality of colors comprise at least one of red color, green color, and blue color.

4. The display device of claim 2, wherein the first subpixel or the third subpixel included in at least one adjacent pixel among three pixels adjacent to the one pixel in the first direction and the second direction is a subpixel configured to emit light of a third color among the plurality of colors, wherein the third color is different from the first color and the second color.

5. The display device of claim 1, wherein a plurality of non-white color data lines and one white data line are disposed in each of the plurality of pixels.

6. The display device of claim 5, wherein the same white data line is disposed in the one pixel and another pixel adjacent to the one pixel in the first direction.

7. The display device of claim 5, wherein a same color data line is disposed in the one pixel and two other pixels adjacent to the one pixel in the first direction.

8. The display device of claim 1, wherein at least one of the first subpixel, the second subpixel, and the third subpixel has a flip structure in which positions of a corresponding light emitting area and a corresponding subpixel circuit are reversed.

9. The display device of claim 1, wherein the second subpixel is located between the first subpixel and the third subpixel.

10. The display device of claim 9, wherein the plurality of data lines are disposed respectively in an area adjacent to one side of the first subpixel, an area adjacent to the other side of the first subpixel and one side of the second subpixel, an area adjacent to the other side of the second subpixel and one side of the third subpixel, and an area adjacent to the other side of the third subpixel.

11. The display device of claim 9, wherein a sensing line is disposed in an area adjacent to the other side of the second subpixel and one side of the third subpixel.

12. The display device of claim 11, wherein the sensing line is connected to each of the first subpixel, the second subpixel, and the third subpixel by a branch line running across respective light emitting areas of the first subpixel, the second subpixel, and the third subpixel.

13. The display device of claim 9, the plurality of pixels comprise an adjacent pixel adjacent to the third subpixel included in the one pixel, and a high voltage line is disposed in an area adjacent to one side of the first subpixel in the one pixel and an area adjacent to the other side of the third subpixel in the adjacent pixel, and is not disposed in an area adjacent to the third subpixel in the one pixel and the first subpixel in the adjacent pixel.

14. The display device of claim 1, wherein:
the plurality of pixels comprise a first pixel, a second pixel, a third pixel, a fourth pixel, a fifth pixel, and a sixth pixel sequentially disposed in at least one odd row among a plurality of rows, and a seventh pixel, an eighth pixel, a ninth pixel, a tenth pixel, an eleventh pixel, and a twelfth pixel are sequentially disposed to correspond to locations where the first to sixth pixels are disposed, respectively, in at least one even row among the plurality of rows; and
the first to sixth pixels are connected to a first gate line and a second gate line among the plurality of gate lines, and the seventh to twelfth pixels are connected to a third gate line and a fourth gate line among the plurality of gate lines.

15. The display device of claim 1, further comprising:
a gate driving circuit configured to drive the plurality of gate lines; and
a data driving circuit configured to supply data voltages to the plurality of data lines.

16. The display device of claim 1, wherein at least two of the first subpixel, the second subpixel, or the third subpixel in the one pixel are connected to different gate lines from each other, respectively.

17. A display panel, comprising:
a plurality of pixels that each includes a first subpixel, a second subpixel, and a third subpixel configured to emit light of different colors from each other, wherein the plurality of pixels are connected to a first gate line and a second gate line;
a first color data line running across first, second and third pixels among the plurality of pixels;
a second color data line running across fourth, fifth and sixth pixels among the plurality of pixels;
a first white data line running across the first and second pixels among the plurality of pixels;
a second white data line running across the third and fourth pixels among the plurality of pixels; and
a third white data line running across the fifth and sixth pixels among the plurality of pixels.

18. A display panel comprising:
a plurality of gate lines extending in a first direction,
a plurality of data lines extending in a second direction intersecting the first direction, and
a plurality of pixels each comprising a plurality of subpixels,
wherein a first pixel of the plurality of pixels is connected to the same data line with at least one adjacent other pixel in the first direction.

19. The display panel of claim 18, wherein the data line is a white data line, and the at least one adjacent other pixel includes a second pixel, and
wherein the white data line is disposed in the first pixel and second pixel of the plurality of pixels, and is connected to the first pixel and second pixel.
